(19) United States
(12) Patent Application Publication
(10) Pub. No.: US 2026/0321296 A1
(43) Pub. Date: Oct. 15, 2026

(54) SEMICONDUCTOR DEVICE INCLUDING MEMORY STRUCTURE AND METHOD FOR MANUFACTURING THE SAME

(71) Applicant: TAIWAN SEMICONDUCTOR MANUFACTURING COMPANY, LTD., Hsinchu (TW)

(72) Inventors: Fu-Chen Chang, Hsinchu (TW); Wen-Ting Chu, Hsinchu (TW); Kuo-Chi Tu, Hsinchu (TW); Sheng-Hung Shih, Hsinchu (TW); Wan-Chen Chen, Hsinchu (TW); Chu-Jie Huang, Hsinchu (TW); Tzu-Yu Chen, Hsinchu (TW)

(73) Assignee: TAIWAN SEMICONDUCTOR MANUFACTURING COMPANY, LTD., Hsinchu (TW)

(21) Appl. No.: 19/179,528

(22) Filed: Apr. 15, 2025

(51) Int. Cl. G11C 5/06; H01L 21/033; H01L 21/768; H10B 63/00; H10N 70/00

(52) U.S. Cl. CPC G11C 5/063; H10B 63/34; H10N 70/063; H10N 70/066; H10P 76/405; H10W 20/057

(57) ABSTRACT

A method for manufacturing a semiconductor device includes: forming a metallization layer over a substrate, the metallization layer including a first dielectric layer and a metal line disposed in the first dielectric layer; forming a memory structure on the metal line opposite to the substrate; forming a first mask on the memory structure opposite to the metal line; forming a second dielectric layer to cover the first mask, the memory structure and the metallization layer; conducting a patterning process to form an opening that penetrates the second dielectric layer and the first mask so as to expose an upper surface of the memory structure, an etching rate of the second dielectric layer being greater than an etching rate of the first mask in the patterning process; and forming a conductive material layer to fill the opening so as to obtain an electrode via connected to the memory structure.

### BACKGROUND

Semiconductor devices including memory structures (for example, dynamic random-access memories (DRAMs), static random-access memories (SRAMs), resistive random-access memories (RRAMs), etc.) have been applied in various fields, such as Internet of Things (IoT), artificial intelligence (AI), etc. It is noted that, the RRAMs are regarded as next generation semiconductor memory structures due to their superior performance, such as fast write speed, low energy consumption, and scale-down capability. Nevertheless, there are certain challenges that may need to be overcome with scaling down of the RRAMs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 13 are schematic views illustrating some intermediate stages of the method as depicted in FIG. 1 in accordance with some embodiments.

FIG. 14 is a schematic view illustrating a semiconductor device in accordance with some embodiments.

FIG. 15 is a schematic view illustrating a semiconductor device in accordance with some embodiments.

FIG. 16 is a schematic view illustrating a semiconductor device in accordance with some embodiments.

FIG. 17 is a schematic view illustrating a semiconductor device in accordance with some embodiments.

FIG. 18 is a schematic view illustrating an integrated circuit chip in accordance with some embodiments.

FIG. 19 is a circuit diagram of the integrated circuit chip depicted in FIG. 18 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “bottom,” “top,” “lower,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

A resistive random-access memory (RRAM) is a type of non-volatile random-access memory, and operates by changing the resistance across a dielectric material. A RRAM structure includes a bottom electrode, a top electrode, and a switching layer (made of a dielectric material) disposed between the bottom electrode and the top electrode. In some embodiments, the RRAM structure may be embedded in a metallization layer of an interconnect structure, and a top electrode via (TEVA) penetrates a hard mask (e.g., made of silicon oxynitride) and lands on the top electrode of the RRAM structure.

With continuous development of semiconductor technology and increased demands of integrated circuit (IC) chips, the semiconductor industry is devoted to scaling down semiconductor structures, the interconnect structure, etc. included in the IC chips. Shrinkage of both the RRAM structure and the TEVA may cause the TEVA thus formed to be not successfully landed on the top electrode of the RRAM structure (which may arise from overlay shift), thereby rendering the RRAM structure inoperable.

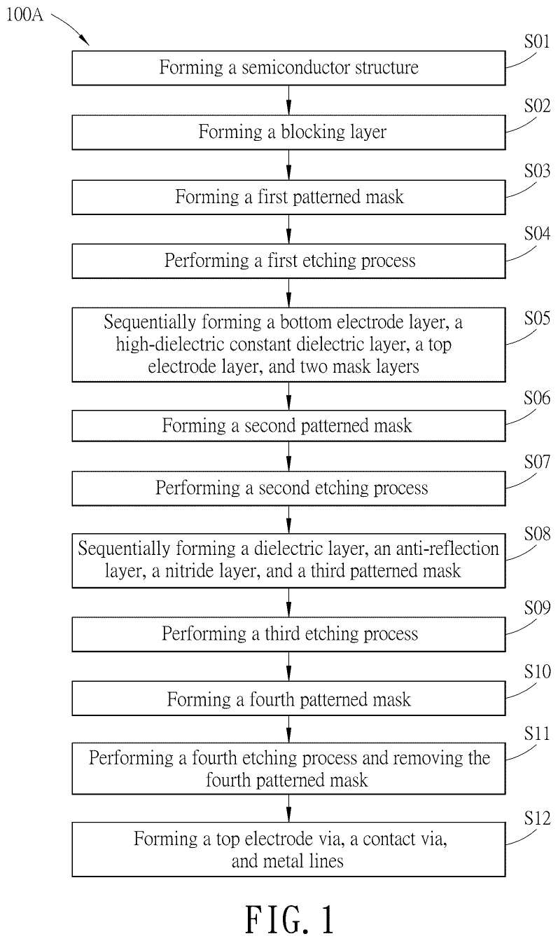

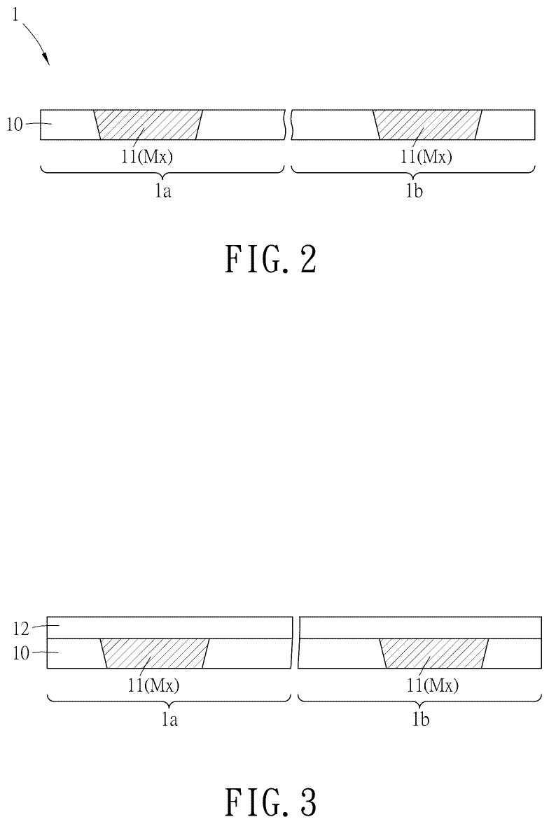

The present disclosure is directed to a semiconductor device and a method for manufacturing the same. FIG. 1 is a flow diagram illustrating a method 100A for manufacturing a first semiconductor device 200A and a second semiconductor device 200B shown in FIG. 13 in accordance with some embodiments. FIGS. 2 to 12 illustrate schematic views of some intermediate stages of the method 100A. Some portions in FIGS. 2 to 12 may be omitted for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step S01, where a semiconductor structure 1 is formed. In some embodiments, the semiconductor structure 1 is formed on a topmost dielectric layer of an interconnect structure (not shown) disposed on a semiconductor substrate (not shown). The semiconductor structure 1 includes a dielectric layer 10 and a plurality of metal lines 11.

The dielectric layer 10 is formed on the topmost dielectric layer of the interconnect structure. In some embodiments, the dielectric layer 10 includes or is made of, for example, but not limited to, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), low-dielectric constant (k) dielectric materials, extreme low-k dielectric materials, or combinations thereof. In some alternative embodiments, the dielectric layer 10 includes or is made of, for example, but not limited to, polyimide, epoxy resin, acrylic resin, phenol resin, benzocyclobutene (BCB), polybenzooxazole (PBO), other suitable polymer-based dielectric materials, or combinations thereof. Other suitable materials for the dielectric layer 10 are within the contemplated scope of the present disclosure. In some embodiments, the dielectric layer 10 may include a memory region 1a and a logic region 1b.

The metal lines 11 are disposed in the dielectric layer 10 and are spaced apart from one another. In some embodiments, the metal lines 11 include or are made of, for example, but not limited to, copper, aluminum, tungsten, or combinations thereof. Other suitable materials for the metal lines 11 are within the contemplated scope of the present disclosure. In some embodiments, each of the metal lines 11 has a cross section of an inverted trapezoid shape. Other geometrical shapes for each of the metal lines 11 are within the contemplated scope of the present disclosure. One of the metal lines 11 is shown in FIG. 2, and is located at each of the memory region 1a and the logic region 1b. It is noted that a number of the metal lines 11 located at the memory region 1a and/or the logic region 1b may be plural.

Referring to FIG. 1 and the example illustrated in FIG. 3, the method 100A then proceeds to step S02, where a blocking layer 12 (for example, but not limited to, a silicide-blocking layer (SBL)) is formed on the structure shown in FIG. 2. In some embodiments, the blocking layer 12 includes or is made of a dielectric material, for example, but not limited to, silicon oxide or silicon nitride. Other suitable materials for forming the blocking layer 12 are within the contemplated scope of the present disclosure. In some embodiments, the blocking layer 12 is formed by a suitable deposition process, for example, but not limited to, physical vapor deposition (PVD), chemical vapor deposition (CVD), or atomic layer deposition (ALD). Other suitable deposition processes for forming the blocking layer 12 are within the contemplated scope of the present disclosure.

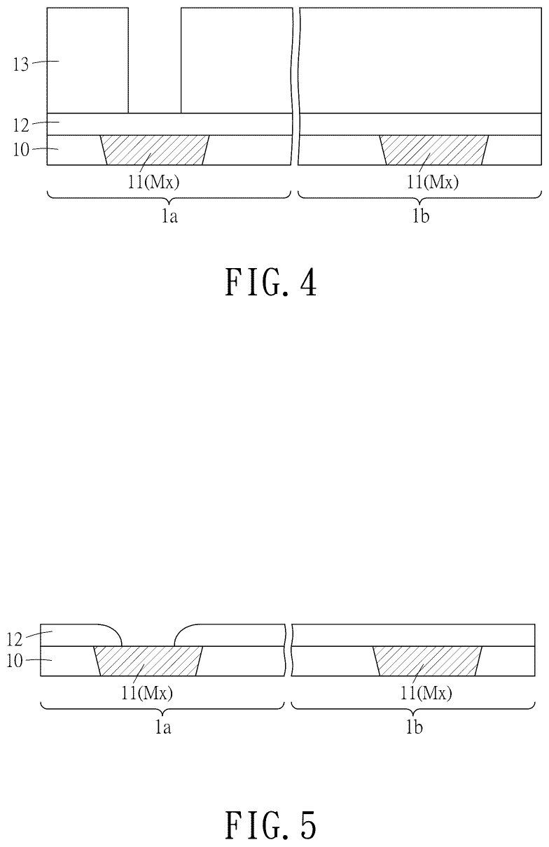

Referring to FIG. 1 and the example illustrated in FIG. 4, the method 100A then proceeds to step S03, where a first patterned mask 13 is formed on the structure shown in FIG. 3. In some embodiments, the first patterned mask 13 includes or is made of, for example, but not limited to, a photoresist material. Other suitable materials for forming the first patterned mask 13 are within the contemplated scope of the present disclosure. In some embodiments, the first patterned mask 13 is formed by coating a photoresist material layer (not shown) on the structure obtained after formation of the blocking layer 12, soft-baking the photoresist material layer, exposing the photoresist material layer through a photomask (not shown), post-exposure baking the photoresist material layer, and developing the photoresist material layer, followed by hard-baking the photoresist material layer to thereby form the first patterned mask 13. In some embodiments, a portion of the blocking layer 12 is exposed from the first patterned mask 13.

In some embodiments, the first patterned mask 13 may be formed as a stack structure including a patterned photoresist layer, a patterned anti-reflection layer (for example, but not limited to, a patterned nitrogen-free anti-reflection layer (NFARL)), a patterned bottom layer, a patterned middle layer, or combinations thereof. In some embodiments, the patterned anti-reflection layer includes or is made of, for example, but not limited to, a nitrogen-free oxide (e.g., silicon oxide). In some embodiments, the patterned bottom layer includes or is made of, for example, but not limited to, an organic material containing carbon, hydrogen, oxygen, or combinations thereof. In some embodiments, the patterned middle layer includes or is made of, for example, but not limited to, an organic material containing carbon, hydrogen, oxygen, or combinations thereof. Other suitable materials for forming each of the patterned anti-reflection layer, the patterned bottom layer, and the patterned middle layer are within the contemplated scope of the present disclosure.

Referring to FIG. 1 and the example illustrated in FIG. 5, the method 100A then proceeds to step S04, where a portion of the blocking layer 12 is removed through the first patterned mask 13. Step S04 is performed by an etching process. In some embodiments, the etching process is, for example, but not limited to, a dry etching process. Other suitable etching processes are within the contemplated scope of the present disclosure. After this step, a portion of an upper surface of one of the metal lines 11 at the memory region 1a is exposed from an opening of the blocking layer 12. In some embodiments, the first patterned mask 13 is removed by a suitable removal process after this step.

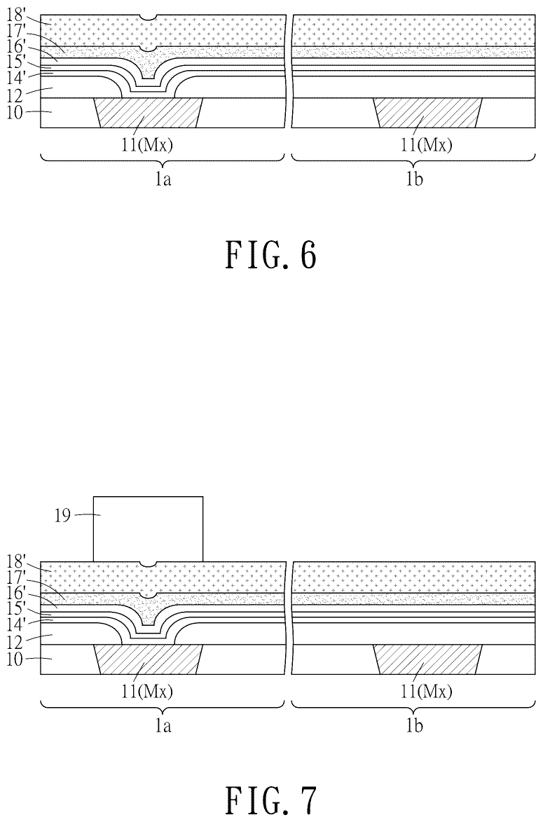

Referring to FIG. 1 and the example illustrated in FIG. 6, the method 100A then proceeds to step S05, where a bottom electrode layer 14′, a high-dielectric constant (k) dielectric layer 15′, a top electrode layer 16′, a mask layer 17′, and a mask layer 18′ are sequentially formed on the structure shown in FIG. 5.

In this step, the bottom electrode layer 14′ is firstly formed on the structure shown in FIG. 5. In some embodiments, the bottom electrode layer 14′ includes or is made of, for example, but not limited to, tungsten, tantalum, tantalum nitride, titanium nitride, or combinations thereof. Other suitable materials for forming the bottom electrode layer 14′ are within the contemplated scope of the present disclosure. In some embodiments, the bottom electrode layer 14′ is formed by a suitable deposition process, for example, but not limited to, CVD, PVD, or ALD. Other suitable deposition processes for forming the bottom electrode layer 14′ are within the contemplated scope of the present disclosure.

Next, the high-k dielectric layer 15′ is formed on the bottom electrode layer 14′ opposite to the dielectric layer 10. In some embodiments, the high-k dielectric layer 15′ includes or is made of, for example, but not limited to, binary oxides, ternary oxides, quaternary oxides, or combinations thereof. The binary oxides may include, for example, but not limited to, hafnium oxide. The ternary oxides may include, for example, but not limited to, hafnium silicate, hafnium zirconate, barium titanate, lead titanate, strontium titanate, calcium manganite, bismuth ferrite, doped hafnium oxide (the dopants may include yttrium, scandium, gallium, gadolinium, or combinations thereof), or combinations thereof. The quaternary oxides may include, for example, but not limited to, lead zirconate titanate, barium strontium titanate, strontium bismuth tantalate, or combinations thereof. Other suitable materials for forming the high-k dielectric layer 15′ are within the contemplated scope of the present disclosure. In some embodiments, the high-k dielectric layer 15′ is formed by a suitable deposition process, for example, but not limited to, CVD, PVD, or ALD. Other suitable deposition processes for forming the high-k dielectric layer 15′ are within the contemplated scope of the present disclosure.

Then, the top electrode layer 16′ is formed on the high-k dielectric layer 15′ opposite to the bottom electrode layer 14′. In some embodiments, the top electrode layer 16′ includes or is made of, for example, but not limited to, tungsten, tantalum, tantalum nitride, titanium nitride, or combinations thereof. Other suitable materials for forming the top electrode layer 16′ are within the contemplated scope of the present disclosure. In some embodiments, the top electrode layer 16′ is formed by a suitable deposition process, for example, but not limited to, CVD, PVD, or ALD. Other suitable deposition processes for forming the top electrode layer 16′ are within the contemplated scope of the present disclosure.

Thereafter, the mask layer 17′ is formed on the top electrode layer 16′ opposite to the high-k dielectric layer 15′. In some embodiments, the mask layer 17′ includes or is made of, for example, but not limited to, an oxide-based material (e.g., silicon oxide (SiOx)), a nitride-based material (e.g., silicon nitride (SiNx)), silicon oxynitride (SiOxNy), silicon oxycarbide, silicon carbide, silicon carbide doped with nitrogen, or combinations thereof. Other suitable materials for forming the mask layer 17′ are within the contemplated scope of the present disclosure. In some embodiments, when the mask layer 17′ includes or is made of silicon oxide (SiOx), an etching rate of the mask layer 17′ may be decreased with a reduction in the atomic percentage (i.e., the x value) of oxygen atoms of silicon oxide. In some embodiments, when the mask layer 17′ includes or is made of silicon nitride (SiNx), the etching rate of the mask layer 17′ may be decreased with an increase in the atomic percentage (i.e., the x value) of nitrogen atoms of silicon nitride. In some embodiments, an etching rate of the nitride-based material is lower than an etching rate of the oxide-based material. In some embodiments, the mask layer 17′ is formed by a suitable deposition process, for example, but not limited to, CVD or PVD. Other suitable deposition processes for forming the mask layer 17′ are within the contemplated scope of the present disclosure. In some embodiments, the mask layer 17′ has a thickness ranging from about 1 nm to about 100 nm. If the thickness of the mask layer 17′ is greater than 100 nm, a cost for manufacturing the first semiconductor device 200A may be increased.

Afterwards, the mask layer 18′ is formed on the mask layer 17′ opposite to the to electrode layer 16′. The process for forming the mask layer 18′ is the same as or similar to that for forming the mask layer 17′, and thus details thereof are omitted for the sake of brevity. In some embodiments, a ratio of an etching rate of the mask layer 18′ to the etching rate of the mask layer 17′ is greater than about 1. That is, the etching rate of the mask layer 18′ is greater than the etching rate of the mask layer 17′. In some embodiments, the mask layer 18′ includes or is made of, for example, but not limited to, an oxide-based material (e.g., silicon oxide (SiOx)), a nitride-based material (e.g., silicon nitride (SiNx)), silicon oxynitride (SiOxNy), silicon oxycarbide, silicon carbide, silicon carbide doped with nitrogen, or combinations thereof. Other suitable materials for forming the mask layer 18′ are within the contemplated scope of the present disclosure. When each of the mask layer 17′ and the mask layer 18′ includes or is made of silicon oxide (SiOx), the atomic percentage (i.e., the x value) of oxygen atoms included in the mask layer 17′ is lower than that of oxygen atoms included in the mask layer 18′. When each of the mask layer 17′ and the mask layer 18′ includes or is made of silicon nitride (SiNx), the atomic percentage (i.e., the x value) of nitrogen atoms included in the mask layer 17′ is greater than that of nitrogen atoms included in the mask layer 18′. In some embodiments, the mask layer 18′ has a thickness which is greater than about 0 nm and which is up to about 100 nm. If the thickness of the mask layer 18′ is greater than 100 nm, the cost for manufacturing the first semiconductor device 200A may be increased. In some embodiments, a ratio of the thickness of the mask layer 18′ to the thickness of the mask layer 17′ ranges from about 0.01 to about 100.

Referring to FIG. 1 and the example illustrated in FIG. 7, the method 100A then proceeds to step S06, where a second patterned mask 19 is formed on the structure shown in FIG. 6. The materials and processes for forming the second patterned mask 19 are the same as or similar to those for forming the first patterned mask 13, and thus details thereof are omitted for the sake of brevity. In some embodiments, the second patterned mask 19 may be formed as a stack structure which includes a patterned photoresist layer, a patterned bottom layer, a patterned middle layer, or combinations thereof.

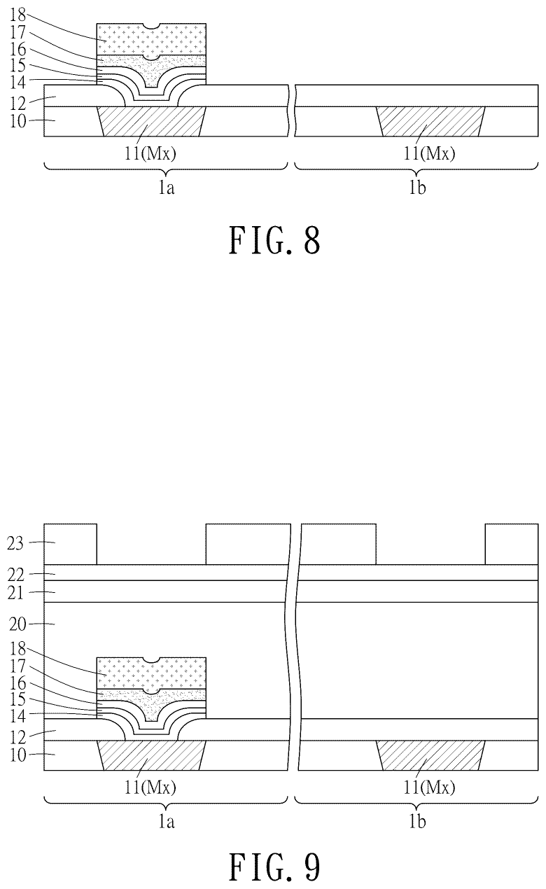

Referring to FIG. 1 and the example illustrated in FIG. 8, the method 100A then proceeds to step S07, where a portion of the mask layer 18′, a portion of the mask layer 17′, a portion of the top electrode layer 16′, a portion of the high-k dielectric layer 15′, and a portion of the bottom electrode layer 14′ are removed through the second patterned mask 19. Step S07 is performed by an etching process. In some embodiments, the etching process is, for example, but not limited to, a dry etching process. Other suitable etching processes are within the contemplated scope of the present disclosure. After step S07, the mask layer 18′ is formed into a mask 18 (i.e., a remaining portion of the mask layer 18′); the mask layer 17′ is formed into a mask 17 (i.e., a remaining portion of the mask layer 17′); the top electrode layer 16′ is formed into a top electrode 16 (i.e., a remaining portion of the top electrode layer 16′); the high-k dielectric layer 15′ is formed into a high-k dielectric layer portion 15 (i.e., a remaining portion of the high-k dielectric layer 15′); and the bottom electrode layer 14′ is formed into a bottom electrode 14 (i.e., a remaining portion of the bottom electrode layer 14′). It is noted that a number of each of the bottom electrode 14, the high-k dielectric layer portion 15, the top electrode 16, the mask 17, and the mask 18 may be plural. In some embodiments, the bottom electrode 14, the high-k dielectric layer portion 15, and the top electrode 16 may be collectively referred to as a memory structure. It is noted that a number of the memory structure may be plural. The bottom electrode 14 of the memory structure is in direct contact with the upper surface of a corresponding one of the metal lines 11 at the memory region 1a. The high-k dielectric layer portion 15 serves as a switching layer of the memory structure. In some embodiments, the second patterned mask 19 is removed by a suitable removal process after this step.

Referring to FIG. 1 and the example illustrated in FIG. 9, the method 100A then proceeds to step S08, where a dielectric layer 20, an anti-reflection layer 21, a nitride layer 22, and a third patterned mask 23 are sequentially formed on the structure shown in FIG. 8.

In this step, the dielectric layer 20 is firstly formed on the structure shown in FIG. 8. The material for forming the dielectric layer 20 is the same as or similar to that for forming the dielectric layer 10, and thus details thereof are omitted for the sake of brevity. In some embodiments, the dielectric layer 20 is formed by a suitable deposition process, for example, but not limited to, CVD. Other suitable deposition processes for forming the dielectric layer 20 are within the contemplated scope of the present disclosure. In some embodiments, a dielectric constant of the dielectric layer 20 is different from that of the dielectric layer 10. In some embodiments, an etching rate of the dielectric layer 20 is greater than or equal to an etching rate of the mask 18 (or the mask layer 18′), and thus is greater than an etching rate of the mask 17 (or the mask layer 17′). In some embodiments, a ratio of the etching rate of the dielectric layer 20 to the etching rate of the mask 18 (or the mask layer 18′) is greater than or equal to about 1, and a ratio of the etching rate of the dielectric layer 20 to the etching rate of the mask 17 (or the mask layer 17′) is greater than about 1.

Next, the anti-reflection layer 21 (for example, but not limited to, an NFARL) is formed on the dielectric layer 20 opposite to the dielectric layer 10. In some embodiments, the anti-reflection layer 21 includes or is made of, for example, but not limited to, a nitrogen-free oxide (e.g., silicon oxide). Other suitable materials for forming the anti-reflection layer 21 are within the contemplated scope of the present disclosure. In some embodiments, the anti-reflection layer 21 is formed by a suitable deposition process, for example, but not limited to, CVD. Other suitable deposition processes for forming the anti-reflection layer 21 are within the contemplated scope of the present disclosure.

Then, the nitride layer 22 is formed on the anti-reflection layer 21 opposite to the dielectric layer 20. In some embodiments, the nitride layer 22 includes or is made of, metal nitride (for example, but not limited to, titanium nitride). Other suitable materials for forming the nitride layer 22 are within the contemplated scope of the present disclosure. In some embodiments, the nitride layer 22 is formed by a suitable deposition process, for example, but not limited to, CVD, PVD, or ALD. Other suitable deposition processes for forming the nitride layer 22 are within the contemplated scope of the present disclosure.

Thereafter, the third patterned mask 23 is formed on the nitride layer 22 opposite to the anti-reflection layer 21. The materials and processes for forming the third patterned mask 23 are the same as or similar to those for forming the first patterned mask 13, and thus details thereof are omitted for the sake of brevity. In some embodiments, the third patterned mask 23 may be formed as a stack structure including a patterned photoresist layer, a patterned bottom layer, a patterned middle layer, or combinations thereof. In some embodiments, portions of the nitride layer 22 are exposed from the third patterned mask 23.

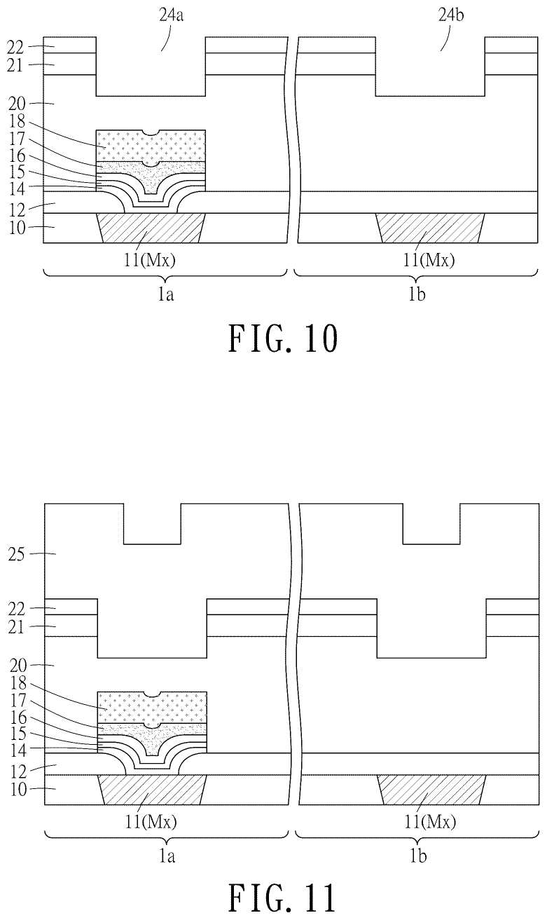

Referring to FIG. 1 and the example illustrated in FIG. 10, the method 100A then proceeds to step S09, where portions of the nitride layer 22, portions of the anti-reflection layer 21, and portions of the dielectric layer 20 are removed through the third patterned mask 23. Step S09 is performed by an etching process. In some embodiments, the etching process is, for example, but not limited to, a dry etching process. Other suitable etching processes are within the contemplated scope of the present disclosure. After this step, two openings 24a, 24b are formed. The opening 24a is located at the memory region 1a, and the opening 24b is located at the logic region 1b. Each of the openings 24a, 24b extends through the nitride layer 22 and the anti-reflection layer 21, and extends into the dielectric layer 20. It is noted that a number of each of the openings 24a, 24b may be plural. In some embodiments, the third patterned mask 23 is removed by a suitable removal process.

Referring to FIG. 1 and the example illustrated in FIG. 11, the method 100A then proceeds to step S10, where a fourth patterned mask 25 is formed on the structure shown in FIG. 10. The materials and processes for forming the fourth patterned mask 25 are the same as or similar to those for forming the first patterned mask 13, and thus details thereof are omitted for the sake of brevity. In some embodiments, the fourth patterned mask 25 may be formed as a stack structure including a patterned photoresist layer, a patterned bottom layer, a patterned middle layer, or combinations thereof.

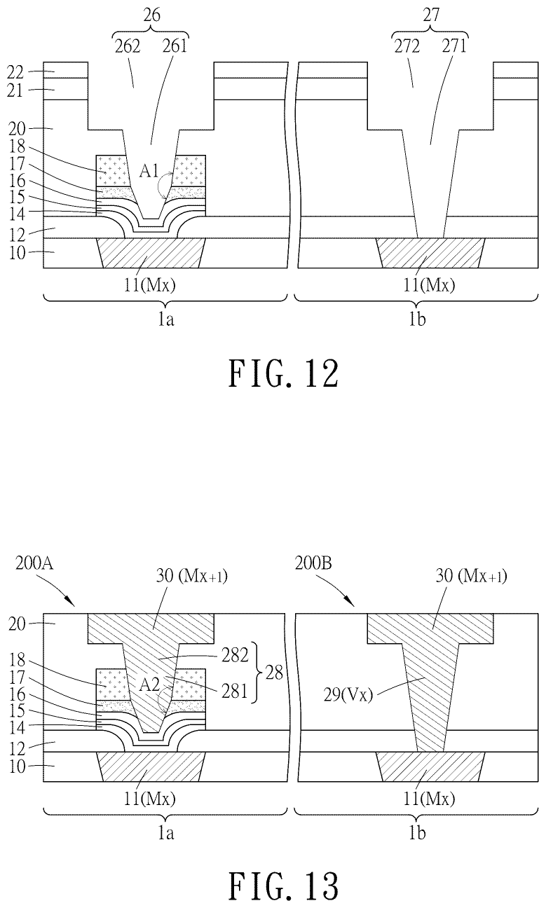

Referring to FIG. 1 and the example illustrated in FIG. 12, the method 100A then proceeds to step S11, where parts of a remaining portion of the dielectric layer 20 are removed through the fourth patterned mask 25. Step S11 is performed by an etching process. In some embodiments, the etching process is, for example, but not limited to, a dry etching process. Other suitable etching processes are within the contemplated scope of the present disclosure. The fourth patterned mask 25 is removed by a suitable removal process after the etching process. After this step, two openings 26, 27 are formed. The opening 26 is located at the memory region 1a, and the opening 27 is located at the logic region 1b.

The opening 26 includes a lower opening portion 261 (a via opening) and an upper opening portion 262 (a trench) in spatial communication with the lower opening portion 261. The upper opening portion 262 of the opening 26 extends through the nitride layer 22 and the anti-reflection layer 21, and into an upper portion of the dielectric layer 20. The lower opening portion 261 of the opening 26 extends downwardly and is tapered from the upper opening portion 262 and through a lower portion of the dielectric layer 20, the mask 18 and the mask 17, and terminates at the top electrode 16. In some embodiments, a size of the upper opening portion 262 of the opening 26 is larger than that of the lower opening portion 261 of the opening 26. In some embodiments, the lower opening portion 261 of the opening 26 has a cross section of a tapered shape. In some embodiments, the lower opening portion 261 of the opening 26 is defined by an opening-defining wall which includes a lower wall portion defined by the mask 17 and an upper wall portion defined by the dielectric layer 20 and the mask 18. In some embodiments, an included angle (A1) between the lower wall portion and the upper wall portion is smaller than about 180 degrees.

The opening 27 includes a lower opening portion 271 (a via opening) and an upper opening portion 272 (a trench) in spatial communication with the lower opening portion 271. The upper opening portion 272 of the opening 27 extends through the nitride layer 22 and the anti-reflection layer 21, and into the upper portion of the dielectric layer 20. The lower opening portion 271 of the opening 27 extends downwardly from the upper opening portion 272 and through the lower portion of the dielectric layer 20 and the blocking layer 12, and terminates at a corresponding one of the metal lines 11 disposed at the logic region 1b. In some embodiments, the lower opening portion 271 of the opening 27 has a cross section of a tapered shape. In some embodiments, the lower opening portion 271 of the opening 27 has a cross section of an inverted trapezoid. Other geometrical shapes for the lower opening portion 271 of the opening 27 are within the contemplated scope of the present disclosure. In some embodiments, a size of the upper opening portion 272 of the opening 27 is larger than that of the lower opening portion 271 of the openings 27.

Referring to FIG. 1 and the example illustrated in FIG. 13, the method 100A then proceeds to step S12, where a top electrode via (TEVA) 28, a contact via 29 (a metal via (Vₓ)), and a plurality of metal lines 30 (a metallization layer (Mₓ₊₁)) are formed. Step S12 is performed by depositing a conductive material layer for forming the TEVA 28, the contact via 29, and the metal lines 30 on the structure shown in FIG. 12 such that the conductive material layer fills the openings 26, 27, followed by removing an excess portion of the conductive material layer, thereby obtaining the TEVA 28, the contact via 29 (the metal via (Vx)), and the metal lines 30 (the metallization layer (Mₓ₊₁)). In some embodiments, the conductive material layer includes or is made of, for example, but not limited to, copper, aluminum, tungsten, or combinations thereof. Other suitable materials for forming the conductive material layer are within the contemplated scope of the present disclosure. In some embodiments, the conductive material layer is formed by a suitable process, for example, but not limited to, CVD or electroplating. Other suitable processes for forming the conductive material layer are within the contemplated scope of the present disclosure. In some embodiments, the excess portion of the conductive material layer is removed by a suitable removal process, for example, but not limited to, chemical mechanical polishing (CMP). Other suitable removal processes for removing the excess portion of the conductive material layer are within the contemplated scope of the present disclosure. It is noted that a number of each of the TEVA 28 and the contact via 29 may be plural.

The TEVA 28 has a cross section of a tapered shape, which results from the tapered shape of the cross section of the lower opening portion 261 of the opening 26 (with reference to FIG. 12). The TEVA 28 is connected to the top electrode 16 of the memory structure, and includes a lower via portion 281 and an upper via portion 282 connected to the lower via portion 281. A horizontal cross-sectional size of the upper via portion 282 of the TEVA 28 is larger than that of the lower via portion 281 of the TEVA 28. In some embodiments, the lower via portion 281 of the TEVA 28 has a lower side wall in lateral contact with the mask 17, and an upper side wall in lateral contact with the mask 18. In some embodiments, an included angle (A2) between the lower side wall and the upper side wall is smaller than about 180 degrees.

In some embodiments, steps S10 and S11 (formation of the TEVA 28, the contact via 29, and the metal lines 30) may be referred to as a dual damascene process. In some embodiments, the TEVA 28, the contact via 29, and the metal lines 30 may be formed separately and sequentially using two single damascene processes.

After step S11, the first semiconductor device 200A and the second semiconductor device 200B are obtained. Because the lower opening portion 261 of the opening 26 has the tapered profile shown in FIG. 12, which is caused by different etching rates of the mask layer 17′, the mask layer 18′, and the dielectric layer 20 as described above, the TEVA 28 is formed tapered (the cross section of the TEVA 28 has the tapered shape), and may be fully disposed on the top electrode 16 of the memory structure, even though when the TEVA 28 is misaligned with the memory structure in a landing process. Therefore, the TEVA 28 can avoid covering a side wall of the memory structure, and failure of the memory structure (i.e., the bottom electrode 14 and the top electrode 16 being electrically connected to each other through the TEVA 28) can be prevented. In addition, when a memory structure and a TEVA disposed on the memory structure are scaled down, a contact resistance (Rc) therebetween may be increased. In the first semiconductor device 200A, an increase in a contact resistance (Rc) between the TEVA 28 and the memory structure can be avoided because only the lower via portion 281 of the TEVA 28 is scaled down.

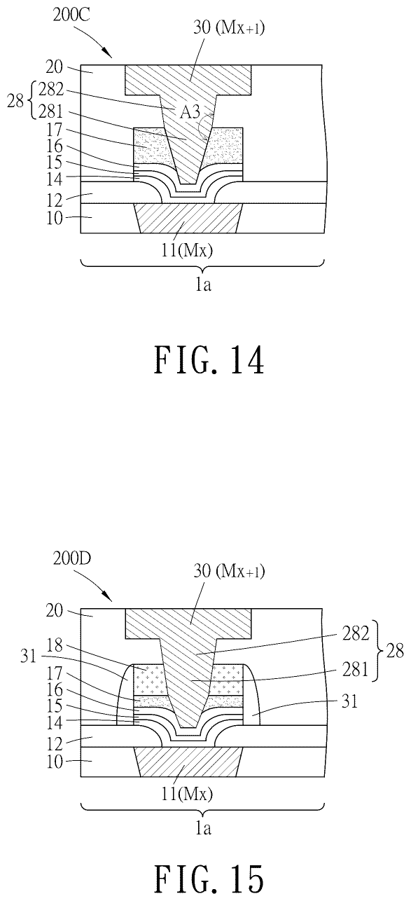

FIG. 14 illustrates a third semiconductor device 200C in accordance with some embodiments. A structure of the third semiconductor device 200C is generally similar to that of the first semiconductor device 200A, except that the third semiconductor device 200C does not include the mask 18 (i.e., the mask layer 18′ is not formed in step S05). In this case, the mask 17 (or the mask layer 17′) does not include or is not made of silicon oxynitride. In addition, the lower via portion 281 has a lower side wall in lateral contact with the mask 17, and the upper via portion 282 has an upper side wall in lateral contact with the dielectric layer 20. In some embodiments, an included angle (A3) between the upper side wall of the upper via portion 282 and the lower side wall of the lower via portion 281 is smaller than about 180 degrees.

FIG. 15 illustrates a fourth semiconductor device 200D in accordance with some embodiments. A structure of the fourth semiconductor device 200D is generally similar to that of the first semiconductor device 200A, except that the fourth semiconductor device 200D further includes a pair of spacers 31. The spacers 31 are disposed on the blocking layer 12, and laterally cover each of the mask 18, the mask 17, the top electrode 16, the high-k dielectric layer portion 15, and the bottom electrode 14. In some embodiments, each of the spacers 31 includes or is made of, for example, but not limited to, silicon nitride, silicon carbide, or a combination thereof. Other suitable materials for forming the spacers 31 are within the contemplated scope of the present disclosure.

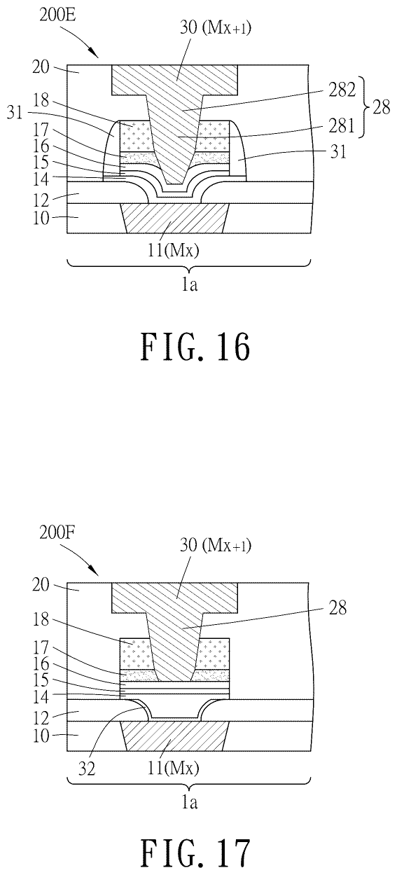

FIG. 16 illustrates a fifth semiconductor device 200E in accordance with some embodiments. A structure of the fifth semiconductor device 200E is generally similar to that of the fourth semiconductor device 200D, except that in the fifth semiconductor device 200E, the spacers 31 are disposed on two opposite sides of the bottom electrode 14, and laterally cover each of the mask 18, the mask 17, the top electrode 16, and the high-k dielectric layer portion 15.

FIG. 17 illustrates a sixth semiconductor device 200F in accordance with some embodiments. A structure of the sixth semiconductor device 200F is generally similar to that of the first semiconductor device 200A, except that the sixth semiconductor device 200F further includes a barrier 32, and a cross-sectional shape of each of the bottom electrode 14, the high-k dielectric layer portion 15, and the top electrode 16 of the sixth semiconductor device 200F is different from that of each of the bottom electrode 14, the high-k dielectric layer portion 15, and the top electrode 16 of the first semiconductor device 200A. The barrier 32 is disposed on an upper surface of a corresponding one of the metal lines 11, and laterally covers the blocking layer 12. In some embodiments, the barrier 32 includes or is made of metal nitride (for example, but not limited to, tantalum nitride). Other suitable materials for the barrier 32 are within the contemplated scope of the present disclosure. The barrier 32 may prevent metal atoms of the corresponding one of the metal lines 11 from diffusing into the bottom electrode 14.

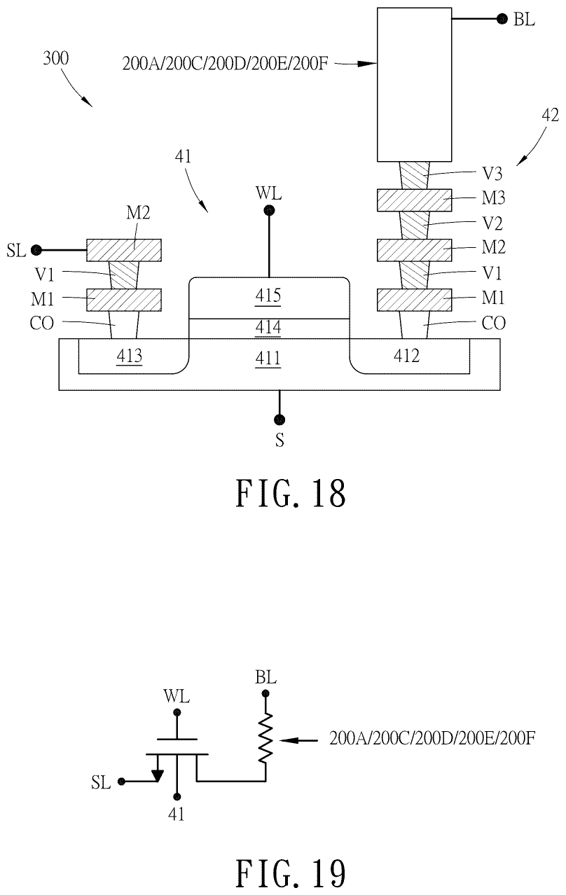

FIG. 18 illustrates an integrated circuit (IC) chip 300 in accordance with some embodiments. FIG. 19 is a circuit diagram of the IC chip 300. The IC chip 300 includes a circuit device 41, an interconnect structure 42, and a semiconductor device.

The circuit device 41 includes a substrate 411, two source/drain regions 412, 413, and a gate structure.

In some embodiments, the substrate 411 includes or is made of, for example, but not limited to, silicon. Other suitable materials for the substrate 411 are within the contemplated scope of the present disclosure.

The source/drain regions 412, 413 are disposed in the substrate 411, and are spaced apart from each other. In some embodiments, each of the source/drain regions 412, 413 has an n-type conductivity or a p-type conductivity.

The gate structure is disposed on the substrate 411, and includes a gate dielectric 414 and a gate electrode 415 disposed on the gate dielectric 414 opposite to the substrate 411. In some embodiments, the gate dielectric 414 includes or is made of, for example, but not limited to, silicon oxide, silicon oxynitride, silicon nitride, high-k dielectric material (e.g., hafnium oxide, hafnium silicate, hafnium silicon oxynitride, hafnium tantalate, hafnium titanate, or hafnium zirconium oxide), or combinations thereof. In some embodiments, the gate electrode 415 includes or is made of, for example, but not limited to, a metallic material (e.g., silver, aluminum, copper, tungsten, nickel, etc.), a metal compound (e.g., titanium nitride, tantalum nitride, metal silicide, etc.), polycrystalline silicon, or doped silicon. Other suitable materials for each of the gate dielectric 414 and the gate electrode 415 are within the contemplated scope of the present disclosure.

In some embodiments, the circuit device 41 is a transistor (e.g., an n-type metal-oxide-semiconductor field-effect transistor (NMOSFET), a p-type metal-oxide-semiconductor field-effect transistor (PMOSFET), etc.) or other suitable circuit devices.

The interconnect structure 42 includes two source/drain contacts C0, a plurality of contact vias V1, V2, V3, and a plurality of metal lines M1, M2, M3. The source/drain contacts C0 are disposed on the source/drain regions 412, 413, respectively. The metal lines M1 are disposed on the source/drain contacts C0 opposite to the substrate 411. Each of the source/drain contacts C0 is connected to a corresponding one of the metal lines M1. Each of the contact vias V1 is disposed between and connected to a corresponding one of the metal lines M1 and a corresponding one of the metal lines M2. The contact via V2 is disposed between and connected to a corresponding one of the metal lines M2 and the metal line M3. The contact via V3 is disposed between and connected to the metal line M3 and the semiconductor device. In some embodiments, each of the source/drain contacts C0, the contact vias V1, V2, V3, and the metal lines M1, M2, M3 includes or is made of a conductive material, for example, but not limited to, copper. Other suitable conductive materials for the source/drain contacts C0, the contact vias V1, V2, V3, and the metal lines M1, M2, M3 are within the contemplated scope of the present disclosure.

The semiconductor device is embedded in the interconnect structure 42. In some embodiments, a structure of the semiconductor device is the same as or similar to that of one of the first semiconductor device 200A, the third semiconductor device 200C, the fourth semiconductor device 200D, the fifth semiconductor device 200E, and the sixth semiconductor device 200F.

As shown in FIGS. 18 and 19, one of the metal lines M2 of the interconnect structure 42 is electrically connected to a source line SL, a metal line of the semiconductor device is electrically connected to a bit line BL, and the gate structure is electrically connected to a word line WL.

In this disclosure, a mask is formed on a memory structure, and the mask has an etching rate that is lower than an etching rate of a dielectric layer disposed on the mask and that is lower than an etching rate of another mask (if present) disposed between the mask and the dielectric layer. A top electrode via (TEVA) may be formed tapered such that the TEVA may be fully disposed on the memory structure (e.g., a top electrode of the memory structure), which can prevent a material for forming the TEVA from covering a side wall of the memory structure, and which can avoid a failure of the memory structure (i.e., a bottom electrode and the top electrode of the memory structure being electrically connected to each other).

In accordance with some embodiments of the present disclosure, a method for manufacturing a semiconductor device includes: forming a metallization layer over a substrate, the metallization layer including a first dielectric layer and a metal line disposed in the first dielectric layer; forming a memory structure on the metal line opposite to the substrate; forming a first mask on the memory structure opposite to the metal line; forming a second dielectric layer to cover the first mask, the memory structure and the metallization layer; conducting a patterning process to form an opening that penetrates the second dielectric layer and the first mask so as to expose an upper surface of the memory structure, an etching rate of the second dielectric layer being greater than an etching rate of the first mask in the patterning process; and forming a conductive material layer to fill the opening so as to obtain an electrode via connected to the memory structure.

In accordance with some embodiments of the present disclosure, the method for manufacturing the semiconductor device further includes, after formation of the first mask and before formation of the second dielectric layer, forming a second mask on the first mask opposite to the memory structure. The opening further penetrates the second mask in the patterning process.

In accordance with some embodiments of the present disclosure, a ratio of the etching rate of the second dielectric layer to an etching rate of the second mask is greater than or equal to 1 in the patterning process.

In accordance with some embodiments of the present disclosure, a ratio of the etching rate of the second mask to the etching rate of the first mask is greater than 1 in the patterning process.

In accordance with some embodiments of the present disclosure, each of the first mask and the second mask independently includes silicon oxide, silicon nitride, silicon oxynitride, silicon oxycarbide, silicon carbide, silicon carbide doped with nitrogen, or combinations thereof.

In accordance with some embodiments of the present disclosure, each of the first mask and the second mask includes silicon oxide, and an atomic percentage of oxygen atoms included in the first mask is lower than an atomic percentage of oxygen atoms included in the second mask.

In accordance with some embodiments of the present disclosure, each of the first mask and the second mask includes silicon nitride, and an atomic percentage of nitrogen atoms included in the second mask is lower than an atomic percentage of nitrogen atoms included in the first mask.

In accordance with some embodiments of the present disclosure, the opening includes a lower opening portion and an upper opening portion in spatial communication with the lower opening portion. The lower opening portion is defined by an opening-defining wall which includes a lower wall portion and an upper wall portion. The lower wall portion is defined by the first mask. The upper wall portion is defined by the second mask and the second dielectric layer. An included angle between the lower wall portion and the upper wall portion is smaller than about 180 degrees.

In accordance with some embodiments of the present disclosure, the opening includes a lower opening portion and an upper opening portion in spatial communication with the lower opening portion. The lower opening portion is defined by an opening-defining wall which includes a lower wall portion and an upper wall portion. The lower wall portion is defined by the first mask. The upper wall portion is defined by the second dielectric layer. An included angle between the lower wall portion and the upper wall portion is smaller than about 180 degrees.

In accordance with some embodiments of the present disclosure, a method for manufacturing a semiconductor device includes: forming a metallization layer over a substrate, the metallization layer including a first dielectric layer, and two metal lines disposed in the first dielectric layer and spaced apart from each other, the metallization layer having a first region and a second region, one of the two metal lines being disposed in the first region and the other one of the two metal lines being disposed in the second region; forming a memory structure disposed on and electrically connected to the one of the two metal lines; forming a first mask on the memory structure opposite to the metallization layer; forming a second dielectric layer to cover the first mask, the memory structure and the metallization layer; conducting a patterning process to form a first opening and a second opening, the first opening penetrating the second dielectric layer and the first mask to expose an upper surface of the memory structure, the second opening penetrating the second dielectric layer to expose an upper surface of the other one of the two metal lines, an etching rate of the second dielectric layer being greater than an etching rate of the first mask in the patterning process; and forming a conductive material layer to fill the first opening and the second opening so as to obtain an electrode via connected to the memory structure, and a contact via connected to the other one of the two metal lines.

In accordance with some embodiments of the present disclosure, the method for manufacturing the semiconductor device further includes, after formation of the first mask and before formation of the second dielectric layer, forming a second mask on the first mask opposite to the memory structure. The first opening further penetrates the second mask in the patterning process. The etching rate of the second dielectric layer is greater than or equal to an etching rate of the second mask, and the etching rate of the second mask is greater than the etching rate of the first mask in the patterning process.

In accordance with some embodiments of the present disclosure, the first opening includes a lower opening portion and an upper opening portion in spatial communication with the lower opening portion. The electrode via is formed in the lower opening portion, and includes a lower via portion having a lower side wall and an upper via portion having an upper side wall. An included angle between the lower side wall and the upper side wall is smaller than about 180 degrees.

In accordance with some embodiments of the present disclosure, a semiconductor device includes a substrate, a metallization layer, a memory structure, a first mask, a second dielectric layer, and an electrode via. The metallization layer is disposed over the substrate, and includes a first dielectric layer and a metal line disposed in the first dielectric layer. The memory structure is disposed on and electrically connected to the metal line. The first mask is disposed on the memory structure opposite to the metal line. The second dielectric layer covers the first mask, the memory structure and the metallization layer. The electrode via penetrates the second dielectric layer and the first mask, and is connected to the memory structure. The electrode via includes a lower via portion having a lower side wall, and an upper via portion having an upper side wall. An included angle between the lower side wall and the upper side wall is smaller than about 180 degrees.

In accordance with some embodiments of the present disclosure, the semiconductor device further includes a second mask disposed on the first mask opposite to the memory structure, and the electrode via further penetrates the second mask.

In accordance with some embodiments of the present disclosure, the lower via portion is in lateral contact with the first mask, and the upper via portion is in lateral contact with the second mask and the second dielectric layer.

In accordance with some embodiments of the present disclosure, each of the first mask and the second mask independently includes silicon oxide, silicon nitride, silicon oxynitride, silicon oxycarbide, silicon carbide, silicon carbide doped with nitrogen, or combinations thereof.

In accordance with some embodiments of the present disclosure, the semiconductor device further includes a pair of spacers, and each of the pair of spacers is disposed in the second dielectric layer, and laterally covers the memory structure, the first mask, and the second mask.

In accordance with some embodiments of the present disclosure, a ratio of a thickness of the second mask to a thickness of the first mask ranges from about 0.01 to about 100.

In accordance with some embodiments of the present disclosure, the first mask has a thickness ranging from about 1 nm to about 100 nm.

In accordance with some embodiments of the present disclosure, the lower via portion is in lateral contact with the first mask, and the upper via portion is in lateral contact with the second dielectric layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a metallization layer over a substrate, the metallization layer including a first dielectric layer and a metal line disposed in the first dielectric layer;
forming a memory structure on the metal line opposite to the substrate;
forming a first mask on the memory structure opposite to the metal line;
forming a second dielectric layer to cover the first mask, the memory structure and the metallization layer;
conducting a patterning process to form an opening that penetrates the second dielectric layer and the first mask so as to expose an upper surface of the memory structure, an etching rate of the second dielectric layer being greater than an etching rate of the first mask in the patterning process; and
forming a conductive material layer to fill the opening so as to obtain an electrode via connected to the memory structure.

2. The method as claimed in claim 1, further comprising, after formation of the first mask and before formation of the second dielectric layer, forming a second mask on the first mask opposite to the memory structure, the opening further penetrating the second mask in the patterning process.

3. The method as claimed in claim 2, wherein a ratio of the etching rate of the second dielectric layer to an etching rate of the second mask is greater than or equal to 1 in the patterning process.

4. The method as claimed in claim 2, wherein a ratio of the etching rate of the second mask to the etching rate of the first mask is greater than 1 in the patterning process.

5. The method as claimed in claim 4, wherein each of the first mask and the second mask independently includes silicon oxide, silicon nitride, silicon oxynitride, silicon oxycarbide, silicon carbide, silicon carbide doped with nitrogen, or combinations thereof.

6. The method as claimed in claim 5, wherein each of the first mask and the second mask includes silicon oxide, and an atomic percentage of oxygen atoms included in the first mask is lower than an atomic percentage of oxygen atoms included in the second mask.

7. The method as claimed in claim 5, wherein each of the first mask and the second mask includes silicon nitride, and an atomic percentage of nitrogen atoms included in the second mask is lower than an atomic percentage of nitrogen atoms included in the first mask.

8. The method as claimed in claim 2, wherein the opening includes a lower opening portion and an upper opening portion in spatial communication with the lower opening portion, the lower opening portion being defined by an opening-defining wall which includes a lower wall portion and an upper wall portion, the lower wall portion being defined by the first mask, the upper wall portion being defined by the second mask and the second dielectric layer, an included angle between the lower wall portion and the upper wall portion being smaller than 180 degrees.

9. The method as claimed in claim 1, wherein the opening includes a lower opening portion and an upper opening portion in spatial communication with the lower opening portion, the lower opening portion being defined by an opening-defining wall which includes a lower wall portion and an upper wall portion, the lower wall portion being defined by the first mask, the upper wall portion being defined by the second dielectric layer, an included angle between the lower wall portion and the upper wall portion being smaller than 180 degrees.

10. A method for manufacturing a semiconductor device, comprising:
forming a metallization layer over a substrate, the metallization layer including a first dielectric layer, and two metal lines disposed in the first dielectric layer and spaced apart from each other, the metallization layer having a first region and a second region, one of the two metal lines being disposed in the first region and the other one of the two metal lines being disposed in the second region;
forming a memory structure disposed on and electrically connected to the one of the two metal lines;
forming a first mask on the memory structure opposite to the metallization layer;
forming a second dielectric layer to cover the first mask, the memory structure and the metallization layer;
conducting a patterning process to form a first opening and a second opening, the first opening penetrating the second dielectric layer and the first mask to expose an upper surface of the memory structure, the second opening penetrating the second dielectric layer to expose an upper surface of the other one of the two metal lines, an etching rate of the second dielectric layer being greater than an etching rate of the first mask in the patterning process; and
forming a conductive material layer to fill the first opening and the second opening so as to obtain an electrode via connected to the memory structure, and a contact via connected to the other one of the two metal lines.

11. The method as claimed in claim 10, further comprising, after formation of the first mask and before formation of the second dielectric layer, forming a second mask on the first mask opposite to the memory structure, the first opening further penetrating the second mask in the patterning process, wherein the etching rate of the second dielectric layer is greater than or equal to an etching rate of the second mask, and the etching rate of the second mask is greater than the etching rate of the first mask in the patterning process.

12. The method as claimed in claim 10, wherein the first opening includes a lower opening portion and an upper opening portion in spatial communication with the lower opening portion, the electrode via being formed in the lower opening portion, and including a lower via portion having a lower side wall and an upper via portion having an upper side wall, an included angle between the lower side wall and the upper side wall being smaller than 180 degrees.

13. A semiconductor device, comprising:
a substrate;
a metallization layer disposed over the substrate, and including a first dielectric layer and a metal line disposed in the first dielectric layer;
a memory structure disposed on and electrically connected to the metal line;
a first mask disposed on the memory structure opposite to the metal line;
a second dielectric layer covering the first mask, the memory structure and the metallization layer; and
an electrode via penetrating the second dielectric layer and the first mask, and being connected to the memory structure,
the electrode via including a lower via portion having a lower side wall and an upper via portion having an upper side wall, an included angle between the lower side wall and the upper side wall being smaller than 180 degrees.

14. The semiconductor device as claimed in claim 13, further comprising a second mask disposed on the first mask opposite to the memory structure, the electrode via further penetrating the second mask.

15. The semiconductor device as claimed in claim 14, wherein the lower via portion is in lateral contact with the first mask, and the upper via portion is in lateral contact with the second mask and the second dielectric layer.

16. The semiconductor device as claimed in claim 14, wherein each of the first mask and the second mask independently includes silicon oxide, silicon nitride, silicon oxynitride, silicon oxycarbide, silicon carbide, silicon carbide doped with nitrogen, or combinations thereof.

17. The semiconductor device as claimed in claim 14, further comprising a pair of spacers, each of the pair of spacers being disposed in the second dielectric layer, and laterally covering the memory structure, the first mask, and the second mask.

18. The semiconductor device as claimed in claim 14, wherein a ratio of a thickness of the second mask to a thickness of the first mask ranges from 0.01 to 100.

19. The semiconductor device as claimed in claim 14, wherein the first mask has a thickness ranging from 1 nm to 100 nm.

20. The semiconductor device as claimed in claim 13, wherein the lower via portion is in lateral contact with the first mask, and the upper via portion is in lateral contact with the second dielectric layer.
